(19) United States
(12) Patent Application Publication
(10) Pub. No.: US 2026/0221768 A1
(43) Pub. Date: Jul. 30, 2026

(54) Circuit Breaker Feature for an Electrical Outlet Center, Such As for Use in a Through-the-Wall Generator Power Supply Assembly

(71) Applicant: Reliance Controls Corporation, Racine, WI (US)

(72) Inventors: Curtis N. Kell, Racine, WI (US); Christopher M. Flegel, Racine, WI (US)

(21) Appl. No.: 19/354,269

(22) Filed: Oct. 9, 2025

Related U.S. Application Data
(60) Provisional application No. 63/749,158, filed on Jan. 24, 2025.

(51) Int. Cl. H02J 3/00; F21V 33/00; H01H 13/14; H02J 9/04; H05K 5/02

(52) U.S. Cl. CPC H02J 3/001; H02J 9/04; H05K 5/0217; F21V 33/006; H01H 13/14

(57) ABSTRACT

A power supply system for use with an electrical generator includes a power inlet mounted to an outside surface building wall, and a power receptacle arrangement mounted to an inside surface of the building wall. The power inlet receives power from the generator. An electrical conductor arrangement extends between the power inlet and the power receptacle arrangement for supplying electrical power from the generator. The power receptable arrangement includes a housing, and one or more circuit breakers are contained within the housing. Each circuit breaker may be a pushbutton-type circuit breaker that includes a reset button accessible exteriorly of the housing. A lighting arrangement illuminates a surface of the housing, and is illuminated when the generator supplies power to the housing. The conductor arrangement includes a conduit that extends through the building wall, and conductors extending through the conduit that electrically interconnect the power inlet with the power receptacle arrangement.

### CROSS REFERENCE TO RELATED APPLICATIONS

This application claims the benefit of U.S. provisional patent application Ser. No. 63/749,158 filed Jan. 24, 2025, the entire contents of which are hereby incorporated by reference.

### BACKGROUND AND SUMMARY

There are various ways to supply electrical power from a generator to electrically operated items or equipment located within the interior or a building, such as in the event of a power outage. One arrangement for doing so is shown and described in U.S. Pat. No. 7,909,642 issued Mar. 22, 2011 and entitled Outlet Center for Connecting Multiple Loads to An Auxiliary Power Source, the entire contents of which are hereby incorporated by reference. The arrangement disclosed in the '642 patent generally contemplates a power inlet box secured to an outside surface of a building wall and an outlet center secured to an inside surface of the wall in the same location as the power inlet box. A conduit extends through the wall between the power inlet box and the outlet center, and electrical wiring extends through the conduit to electrically connect an input receptacle associated with the power inlet box with a number of electrical receptacles associated with the outlet center. Electrical power can thus be supplied from a generator, which is plugged into the power inlet box input receptacle, to electrically operated items of equipment that are plugged into the electrical receptacles of the outlet center.

An embodiment of the present invention provides a circuit breaker feature for the outlet center in a generator power supply arrangement such as that described above.

In accordance with an embodiment of the present invention, a power supply system for use with an electrical generator includes a power inlet configured to receive power from the electrical generator, and a power receptacle arrangement. The power inlet is configured to be mounted to an outside surface of a wall of a building, and the receptacle arrangement is configured to be mounted to an inside surface of the building wall. An electrical conductor arrangement extends between the power inlet and the power receptacle arrangement for supplying electrical power to the power receptable arrangement from the electrical generator. The power receptable arrangement includes a housing, as well as one or more circuit breakers within the housing.

The housing may include a lighting arrangement that is operable to illuminate a surface of the housing. The lighting arrangement may be configured to be illuminated when the generator supplies electrical power to the housing.

The electrical conductor arrangement may be a conduit that extends through the building wall, with electrical conductors extending through the conduit that electrically interconnect the power inlet with the power receptacle arrangement.

Each of the one or more circuit breakers may be in the form of a pushbutton-type circuit breaker, which includes a reset button that is accessible exteriorly of the housing.

The present invention also contemplates a power receptacle arrangement for connection in an electrical system of a building. The power receptacle arrangement may include a housing configured to be secured to a wall of the building. The housing defines an interior, and includes a plurality of electrical sockets within the interior. An electrical conductor arrangement is disposed within the housing interior and interconnected with the electrical sockets. One or more circuit breakers are contained within the housing, and are interposed between the electrical conductor arrangement and one or more of the electrical sockets.

Electrical wires are interconnected with the electrical conductor arrangement and extend through an opening in a rear wall forming a part of the housing. The electrical wires are configured to be engaged with a power supply, which may be in the form of an electrical generator. The electrical wires may be interconnected with a power inlet box having a power inlet receptacle, which is configured for engagement with a power supply cord that supplies power to the power inlet receptacle from the electrical generator.

The present invention further contemplates an auxiliary power supply system for a building having a primary power supply. The auxiliary power supply system includes an auxiliary power source for supplying electrical power in the event of a failure of the primary power supply, and a power inlet mounted to an outside surface of a wall of the building. A power receptacle arrangement is mounted to an inside surface of the wall of the building, and an electrical conductor arrangement extends between the power inlet and the power receptacle arrangement for supplying electrical power to the power receptable arrangement from the electrical generator. The power receptable arrangement may be in the form of a housing and includes one or more circuit breakers within the housing.

The electrical conductor arrangement may be in the form of a conduit that extends through the building wall, and electrical conductors extend through the conduit that electrically interconnect the power inlet with the power receptacle arrangement.

Each of the one or more circuit breakers may be in the form of a pushbutton-type circuit breaker, with each pushbutton-type circuit breaker including a reset button that is accessible exteriorly of the housing.

Other aspects, features and advantages of the invention will become apparent to those skilled in the art from the following detailed description and accompanying drawings. It should be understood, however, that the detailed description and specific examples, while indicating certain embodiments of the present invention, are given by way of illustration and not of limitation. Many changes and modifications may be made within the scope of the present invention without departing from the spirit thereof, and the invention includes all such modifications.

### BRIEF DESCRIPTION OF THE DRAWINGS

A clear conception of the advantages and features constituting the present invention, and the construction and operation of typical mechanisms provided with the present invention, will become more readily apparent by referring to the exemplary, and therefore non-limiting, embodiments illustrated in the drawings accompanying and forming a part of this specification, wherein like reference numerals designate the same elements can be several views, and in which:

FIG. 1 is an isometric view of a power supply system for use with an electrical generator, with a power receptable arrangement that includes a circuit breaker feature, in accordance with an embodiment of the present invention;

FIG. 2 is a front isometric view of an outlet center having a circuit breaker feature in accordance with an embodiment of the present invention, which is incorporated into the power supply system of FIG. 1;

FIG. 3 is an isometric view of the internal components contained within the outlet center of FIG. 2; and

FIG. 4 is a rear isometric view of the outlet center of FIG. 2.

In describing the representative embodiment of the invention that is illustrated in the drawings, specific terminology will be resorted to for the sake of clarity. However, it is not intended that the invention be limited to the specific terms so selected, and it is to be understood that each specific term includes all technical equivalents, which operate in a similar manner to accomplish a similar purpose. For example, the words “connected,” “attached,” or terms similar thereto are often used. They are not limited to direct connection but include connection through other elements where such connection would be recognized as being equivalent by those skilled in the art.

### DETAILED DESCRIPTION

An embodiment of the present invention and the various features and advantageous details thereof are explained more fully with reference to the non-limiting embodiments described in detail in the following description.

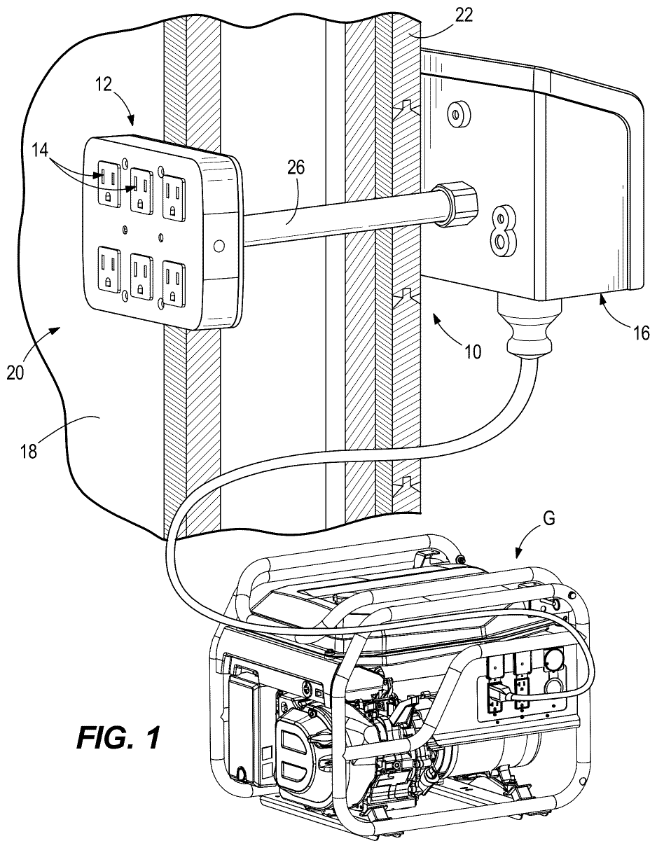

In accordance with an embodiment of the present invention, a through-the-wall generator power supply assembly 10 as shown in FIG. 1 generally includes a wall mounted faceplate or power outlet center 12 that includes a plurality of outlets 14 or sockets that are interconnected to an auxiliary power supply, such as an engine-driven generator G, by means of a wall mounted power inlet box 16. The power outlet center 12 is adapted to be mounted to an interior surface 18 of an exterior wall 20 of a building whereas the power inlet box 16 is adapted to be mounted to an opposite, exterior surface 22 of the exterior wall 20. A conduit 26 may extend between the power outlet center 12 and the power inlet box 16, and electrical conductors such as a series of wires extend through the conduit 26 so that power delivered to the power inlet box 16 is available at the sockets 14 of the power outlet center 12. In an alternative embodiment, a sheathed cable may extend between the power outlet center 12 and the power inlet box 16 instead of the conduit 26 and electrical conductors, so as to supply power from the power inlet box 16 to the power outlet center 12. In either embodiment, the sheathed cable or conduit 26 extends through a bore or passage extending through the wall 20 between the mounted power outlet center 12 and the power inlet box 16.

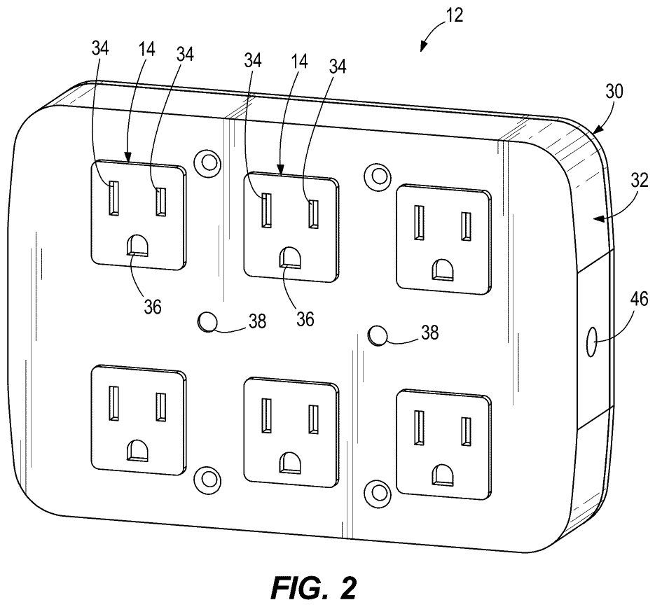

As shown in FIG. 2, the power outlet center 12 according to one embodiment of the invention may include a housing that generally includes a rear plate 30 and a cover 32. The cover 32 has a face within which the sockets 14 are mounted. As known in the art, each socket 14 includes slots 34 configured to receive blades (not shown) of an electrical plug of an electrical load (not shown) or an extension cord (not shown). In the illustrated embodiment, each socket 14 also includes a hole 36 that is configured to receive the ground contact of the plug. While not shown, it is contemplated that the face of the cover 32 may also be provided with one or more USB charging ports, 12V charging ports, etc. The cover 32 also may include a light source, such as a pair of LEDs 38 that are powered during operation of the generator G. The LEDs 38 function as a lighting arrangement to illuminate the surface of the cover 32 and the sockets 14 to assist with inserting plugs into the outlets, and also indicate an operating status of the generator G. Thus, in one embodiment, the power outlet center 12 includes circuitry that detects the operating status of the generator G and illuminates the LEDs 38 accordingly.

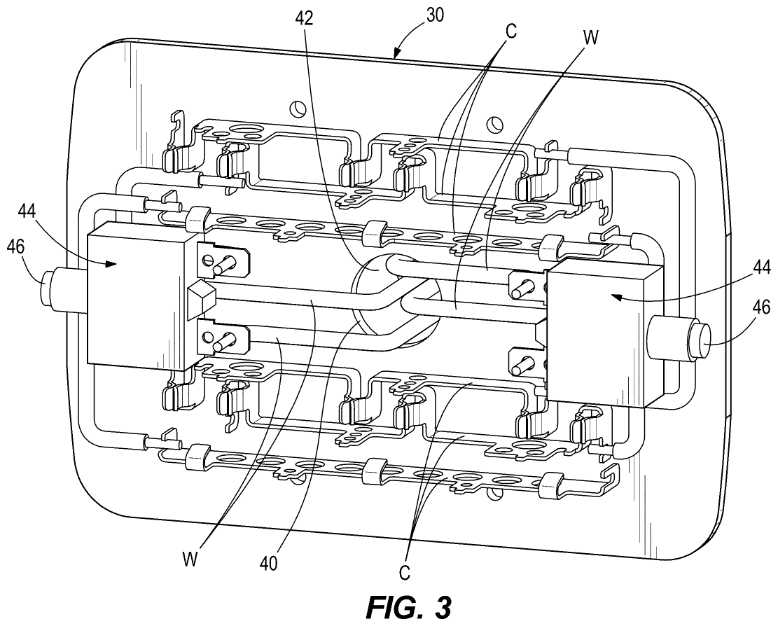

FIG. 3 illustrates the rear plate 30 of the housing of power outlet center 12. The power conductors C for sockets 14 are mounted to the rear plate 30, and power input wires W extend through an opening 40 formed in rear wall 30. A collar 42 extends rearwardly from the rear plate 30, and is configured to receive the inner end of the conduit 26. The power input wires W extend through the conduit 26, and are electrically connected to the power input receptacle of power inlet box 16 in order to supply power to the sockets 14 during operation of the generator G.

In accordance with an embodiment of the present invention, the power outlet center 12 includes a circuit breaker feature. In the illustrated embodiment, the circuit breaker feature is provided by a pair of circuit breakers 44 (FIG. 3), which are secured to the rear plate 30 and are connected between the power input wires W and the power conductors C. In the illustrated embodiment, the circuit breakers 44 are of the type that includes a pushbutton 46 that is employed to reset the circuit breaker, although it is understood that any other satisfactory type or style of circuit breaker may utilized. In the illustrated embodiment, each circuit breaker 44 is connected in series with the conductors C in one of the rows of sockets 14, although again it is understood that any other arrangement of circuit breakers with respect to the sockets of the power outlet center may be employed. When the rear plate 30 and housing cover 32 are assembled together to form the housing of power outlet center 12, the pushbutton 46 of each circuit breaker 44 may be positioned within an opening in a sidewall of housing cover 32.

In operation, when an excessive electrical load is experienced at one or more of the sockets 14, the circuit breaker 44 associated with the overloaded socket 14 is tripped. The user can take steps to alleviate the overload condition, such as by unplugging a load from an effected one of the sockets 14, and can then access the pushbutton 46 of the tripped circuit breaker 44 to reset the circuit breaker, all while remaining indoors.

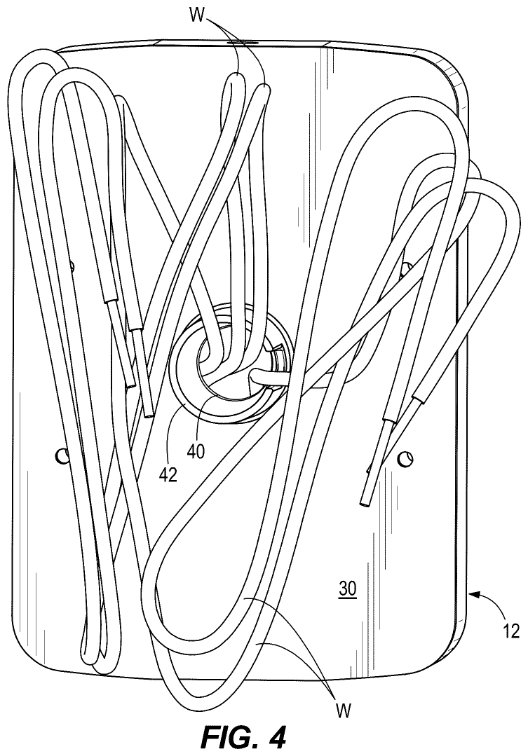

FIG. 4 illustrates the rear plate 30 of power outlet center 12, including the opening 40 and collar 42 that is configured to receive the inner end of the conduit 26. The power input wires W from the interior of the housing extend through the opening 40 and are adapted to be routed through the conduit 26 for connection to the power inlet box 16.

While the power outlet center 12 is shown and described as being used in the through-the-wall generator power supply assembly 10, it is also contemplated that the power outlet center 12 could be employed separately. For example, the power outlet center 12 could be wall mounted and wired into the electrical system of a building, to provide a multi-socket connection point for electrical loads with a circuit breaker feature.

Although the best mode contemplated by the inventor of carrying out the illustrated embodiment of the present invention is disclosed above, practice of the illustrated embodiment of the present invention is not limited thereto. It will be manifest that various additions, modifications and rearrangements of the aspects and features of the embodiment of present invention may be made in addition to those described above without deviating from the spirit and scope of the underlying inventive concept. The scope of some of these changes is discussed above. The scope of other changes to the described embodiments that fall within the present invention but that are not specifically discussed above will become apparent from the appended claims and other attachments. It is also understood that the embodiment of the invention disclosed and defined herein extends to all alternative combinations of two or more of the individual features mentioned or evident from the text and/or drawings. All of these different combinations constitute various alternative aspects of the present invention.

We claim:

1. A power supply system for use with an electrical generator, comprising:
a power inlet configured to receive power from the electrical generator, wherein the power inlet is configured to be mounted to an outside surface of a wall of a building;
a power receptacle arrangement configured to be mounted to an inside surface of the wall of the building; and
an electrical conductor arrangement that extends between the power inlet and the power receptacle arrangement for supplying electrical power to the power receptacle arrangement from the electrical generator;
wherein the power receptacle arrangement comprises a housing and includes one or more circuit breakers within the housing.

2. The power supply system of claim 1, wherein the housing includes a lighting arrangement, wherein the lighting arrangement is operable to illuminate a surface of the housing.

3. The power supply system of claim 2, wherein the lighting arrangement is configured to be illuminated when the generator supplies electrical power to the housing.

4. The power supply system of claim 1, wherein the electrical conductor arrangement comprises a conduit that extends through the building wall, and electrical conductors extending through the conduit that electrically interconnect the power inlet with the power receptacle arrangement.

5. The power supply system of claim 1, wherein each of the one or more circuit breakers comprises a pushbutton-type circuit breaker.

6. The power supply system of claim 5, wherein each pushbutton-type circuit breaker includes a reset button that is accessible exteriorly of the housing.

7. A power receptacle arrangement for connection in an electrical system of a building, comprising:
a housing configured to be secured to a wall of the building, wherein the housing defines an interior and includes a plurality of electrical sockets;
an electrical conductor arrangement disposed within the housing interior and interconnected with the electrical sockets; and
one or more circuit breakers within the housing, wherein the one or more circuit breakers are interposed between the electrical conductor arrangement and one or more of the electrical sockets.

8. The power receptacle arrangement of claim 7, wherein the housing includes a lighting arrangement, wherein the lighting arrangement is operable to illuminate a surface of the housing.

9. The power receptacle arrangement of claim 8, wherein the lighting arrangement is configured to be illuminated when the generator supplies electrical power to the housing.

10. The power receptacle arrangement of claim 7, further comprising electrical wires that are interconnected with the electrical conductor arrangement and that extend through an opening in a rear wall forming a part of the housing, wherein the electrical wires are configured to be engaged with a power supply.

11. The power receptacle arrangement of claim 10, wherein the power supply comprises an electrical generator, and wherein the electrical wires are interconnected with a power inlet box having a power inlet receptacle that is configured for engagement with a power supply cord that supplies power to the power inlet receptacle from the electrical generator.

12. The power receptacle arrangement of claim 10, further comprising conductive terminals within the housing that are interconnected between the electrical conductor arrangement and a power supply.

13. An auxiliary power supply system for a building having a primary power supply, comprising:
an auxiliary power source for supplying electrical power in the event of a failure of the primary power supply;
a power inlet mounted to an outside surface of a wall of the building;
a power receptacle arrangement mounted to an inside surface of the wall of the building; and
an electrical conductor arrangement that extends between the power inlet and the power receptacle arrangement for supplying electrical power to the power receptable arrangement from the electrical generator;
wherein the power receptable arrangement comprises a housing and includes one or more circuit breakers within the housing.

14. The auxiliary power supply system of claim 13, wherein the housing includes a lighting arrangement, wherein the lighting arrangement is operable to illuminate a surface of the housing.

15. The auxiliary power supply system of claim 14, wherein the lighting arrangement is configured to be illuminated when the generator supplies electrical power to the housing.

16. The auxiliary power supply system of claim 13, wherein the electrical conductor arrangement comprises a conduit that extends through the building wall, and electrical conductors extending through the conduit that electrically interconnect the power inlet with the power receptacle arrangement.

17. The auxiliary power supply system of claim 13, wherein each of the one or more circuit breakers comprises a pushbutton-type circuit breaker.

18. The auxiliary power supply system of claim 17, wherein each pushbutton-type circuit breaker includes a reset button that is accessible exteriorly of the housing.
